(19) United States
(12) Patent Application Publication
(10) Pub. No.: US 2020/0080791 A1
(43) Pub. Date: Mar. 12, 2020

(54) HEAT DISSIPATION MODULE

(71) Applicant: FUJIKURA LTD., Tokyo (JP)

(72) Inventors: Yuichi Yokoyama, Tokyo (JP); Youji Kawahara, Tokyo (JP); Yuji Saito, Tokyo (JP)

(73) Assignee: FUJIKURA LTD., Tokyo (JP)

(21) Appl. No.: 16/470,070

(22) PCT Filed: Dec. 14, 2017
(86) PCT No.: PCT/JP2017/044904

§ 371 Date: Jun. 14, 2019

(30) Foreign Application Priority Data
Dec. 20, 2016 (JP) 2016-247075

(51) Int. Cl. F28D 15/04; H01L 23/427; F28D 15/02

(52) U.S. Cl. CPC F28D 15/04; F28D 2021/0028; F28D 15/0233; H01L 23/427

(57) ABSTRACT

A heat dissipation module includes: a container that encloses a working fluid; and a wick disposed inside the container. The container includes: an evaporation portion that evaporates the enclosed working fluid; and a condensation portion that condenses the evaporated working fluid. The wick moves the condensed working fluid from the condensation portion to the evaporation portion using capillary force. The wick includes a plurality of wick portions that form a plurality of liquid flow paths that extend from the condensation portion to the evaporation portion. A vapor flow path of the working fluid is formed between each of the plurality of wick portions, and all of the vapor flow paths are connected in the evaporation portion. The plurality of wick portions includes facing portions that face each other and interpose a vapor flow path at least in the evaporation portion.

### CROSS-REFERENCE TO RELATED APPLICATION

This is a national stage application of International Application No. PCT/JP2017/044904 filed Dec. 14, 2017, which claims priority to Japanese Patent Application No. 2016-247075 filed Dec. 20, 2016, both of which are incorporated herein in their entirety.

### TECHNICAL FIELD

The present invention relates to a heat dissipation module.

### BACKGROUND

Patent Document 1 below discloses a heat pipe as a form of a heat dissipation module. Basically, the heat pipe has a constitution in which a fluid such as water or alcohol to be evaporated and condensed in an aimed temperature range is enclosed as a working fluid inside a container (reservoir) in which a non-condensable gas such as air is degassed, and a wick that generates capillary force in order to return the working fluid in a liquid phase is further provided inside the container.

When a temperature difference is caused in the container, the working fluid is heated and evaporated in a high-temperature evaporation portion, and an internal pressure of the container is also increased. Vapor of the working fluid generated in the evaporation portion is moved to a condensation portion having a low temperature and a low pressure, and heat received in the evaporation portion is transported to the condensation portion as latent heat of the vapor. In the condensation portion, the vapor of the working fluid is condensed by heat dissipation. Then, the condensed working fluid permeates the wick and is returned to the evaporation portion by the capillary force of the wick.

### PATENT DOCUMENT

[Patent Document 1] Japanese Unexamined Patent Application, First Publication No. 11-183069

Operating conditions of a heat dissipation module described above are represented by a calculation formula (a) below in which capillary force is defined as ΔPC, a pressure loss of vapor is defined as ΔPV, and a pressure loss of liquid is defined as ΔPL.

ΔPC≥ΔPV+ΔPL (a)

As it can be grasped from the calculation formula (a), it is necessary to increase the capillary force and reduce the pressure losses of the vapor and the liquid in order to increase a maximum heat transport amount of the heat dissipation module.

In recent years, portable devices such as a smartphone and a tablet PC come to have thinner shapes, and a thin heat dissipation module is demanded in order to dissipate heat of a CPU and the like mounted on such portable devices. In such a thin heat dissipation module, it is necessary to suppress decrease in the maximum heat transport amount, and a devise to keep mechanical strength thereof is required. In other words, as for a relatively large heat dissipation module, it is possible to reduce pressure losses of the vapor and the liquid because a wide vapor flow path and a wide liquid flow path can be secured. However, in a thin heat dissipation module, it is difficult to secure wide space for these flow paths. Additionally, in the thin heat dissipation module, a thickness of a container is also reduced, and it is difficult to secure mechanical strength thereof.

On the other hand, in such a thin heat dissipation module, since a sufficient working fluid is required to be transported to a periphery of an evaporation portion, there may be a case where a plurality of wicks is provided or a wick is divided into a plurality of branches to form a plurality of liquid flow paths. In this case, since tips of the plurality of wicks exist densely in the evaporation portion, a vapor flow path formed between the wicks becomes narrow in this portion, and the pressure loss of the vapor may be locally increased. Additionally, in a case of simply attempting to widen a width of the vapor flow path, a hollow space inside the container is expanded, and therefore, the mechanical strength may be weakened and deformation of the container or the like may be caused.

### SUMMARY

One or more embodiments of the present invention provide a heat dissipation module capable of reducing a pressure loss of vapor of a working fluid and also securing mechanical strength of a container.

A heat dissipation module according to one or more embodiments of the present invention includes: a container enclosing a working fluid therein and including an evaporation portion that evaporates the enclosed working fluid, and a condensation portion that condenses the evaporated working fluid; and a wick arranged inside the container and adapted move the condensed working fluid from the condensation portion to the evaporation portion by capillary force. The wick includes a plurality of wick portions forming a plurality of liquid flow paths extending from the condensation portion to the evaporation portion, the plurality of wick portions includes facing portions facing each other interposing a vapor flow path of the working fluid, and a protruding and recessed portion is formed at least at one of the facing portions.

In one or more embodiments described above, the facing portions may be provided only in the evaporation portion.

In one or more embodiments described above, the protruding and recessed portions may be formed at both of the facing portions, and in the protruding and recessed portions formed at both of the facing portions, a protrusion formed at one of the facing portions may be provided in a manner facing a recess formed at the other facing portion.

In one or more embodiments described above, all of the vapor flow paths may be connected in the evaporation portion.

In one or more embodiments described above, a second protruding and recessed portion may be formed at a tip of a protrusion of the protruding and recessed portion.

In one or more embodiments described above, a column portion may be provided between the plurality of wick portions.

In one or more embodiments described above, a side surface of the column portion may be flat, and the protruding and recessed portion may be formed on a surface of the wick facing the side surface of the column portion.

In one or more embodiments described above, the protruding and recessed portions may be formed at: the facing portions; and the entire side surface of the wick facing the vapor flow paths other than the facing portions.

In one or more embodiments described above, the facing portions may not be necessarily provided in the condensation portion.

In one or more embodiments described above, a protrusion and a recess of the protruding and recessed portion may be formed respectively in triangular shapes in a plan view.

According to one or more embodiments of the present invention described above, it is possible to provide a heat dissipation module capable of reducing a pressure loss of the vapor of the working fluid and also securing mechanical strength of the container.

### BRIEF DESCRIPTION OF THE DRAWINGS

FIG. 1 is a planar cross-sectional view of a vapor chamber according to one or more embodiments of the present invention.

FIG. 2 is a cross-sectional view taken along a line A-A of the vapor chamber illustrated in FIG. 1.

FIG. 3 is an enlarged view of facing portions according to one or more embodiments of the present invention.

FIG. 4 is an enlarged view of a modified example of the facing portions according to one or more embodiments of the present invention.

FIG. 5 is a planar cross-sectional view of a test device to evaluate performance of the vapor chamber according to one or more embodiments of the present invention.

FIG. 6 is a table illustrating test results by the test device illustrated in FIG. 5.

FIG. 7 is a planar cross-sectional view of a modified example of the vapor chamber according to one or more embodiments of the present invention.

FIG. 8A is an enlarged view of another modified example of the facing portions according to one or more embodiments of the present invention.

FIG. 8B is an enlarged view of still another modified example of the facing portions according to one or more embodiments of the present invention.

FIG. 9A is a planar cross-sectional view of a modified example of a protruding and recessed portion according to one or more embodiments of the present invention.

FIG. 9B is a planar cross-sectional view of another modified example of the protruding and recessed portion according to one or more embodiments of the present invention.

FIG. 9C is a planar cross-sectional view of still another modified example of the protruding and recessed portion according to one or more embodiments of the present invention.

### DETAILED DESCRIPTION

Hereinafter, a heat dissipation module and a method of manufacturing the same according to embodiments of the present invention will be described with reference to the drawings. In the drawings, some portions are enlarged or omitted for convenience of description, and a dimensional ratio of each constituent element illustrated in the drawings is not constantly the same as an actual one.

In the following description, a thin vapor chamber will be exemplified as one or more embodiments of the heat dissipation module.

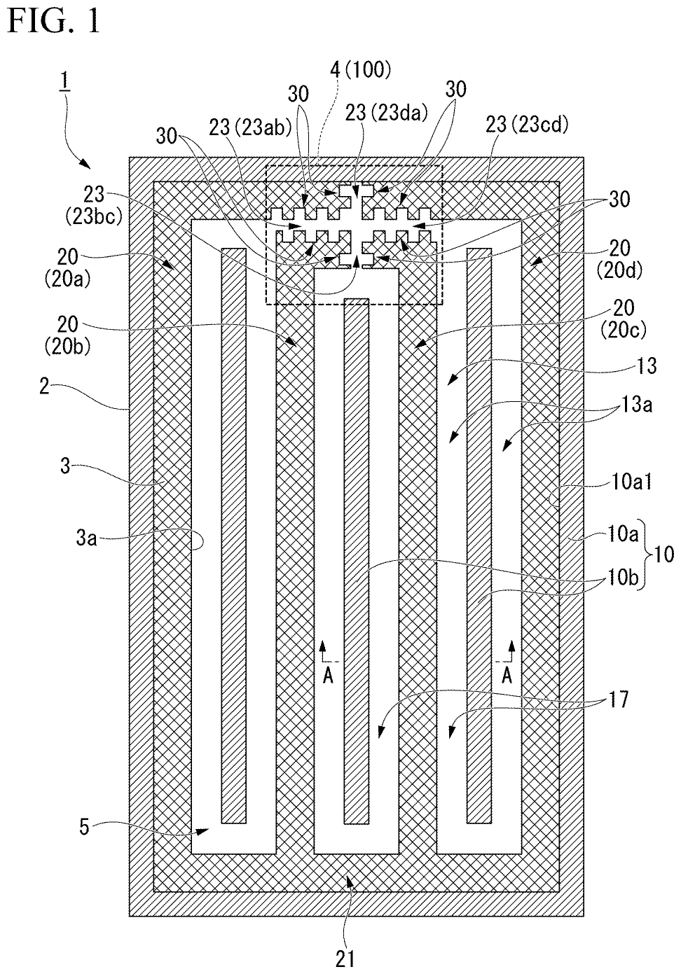

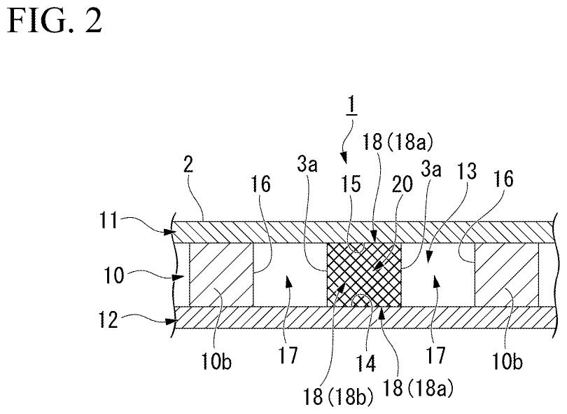

FIG. 1 is a planar cross-sectional view of a vapor chamber 1 according to one or more embodiments. FIG. 2 is a cross-sectional view taken along a line A-A of the vapor chamber 1 illustrated in FIG. 1.

The vapor chamber 1 is a heat transport element utilizing latent heat of a working fluid. As illustrated in FIG. 1, the vapor chamber 1 includes: a container 2 enclosing the working fluid therein; and a wick 3 arranged inside the container 2.

The working fluid is a heat transport medium including a known phase change material, and the phase is changed to a liquid phase and a gas phase inside the container 2. For example, water (pure water), alcohol, ammonia, or the like can be adopted as the working fluid. Note that the working fluid will be described as “working liquid” in the case of the liquid phase and as “vapor” in the case of the gas phase. Additionally, in a case of not distinguishing between the liquid phase and the gas phase, the working fluid may be used for description. Additionally, the working fluid is not illustrated.

The container 2 is a hermetically-sealed hollow container and is formed in a flat shape in which a dimension in a planar direction (vertical and lateral directions in FIG. 1) is larger than a thickness direction (direction perpendicular to a paper surface in FIG. 1, and a vertical direction in FIG. 2). The container 2 has the thickness of, for example, about several tenth of a millimeter to 3 mm. Additionally, the container 2 has a substantially rectangular shape in a plan view from the thickness direction. In the container 2, an evaporation portion 4 that evaporates the enclosed working fluid and a condensation portion 5 that condenses the evaporated working fluid are formed. In one or more embodiments, the evaporation portion 4 is formed in a center of an upper part of the paper surface in FIG. 1.

The evaporation portion 4 is a region that receives heat from a heat source 100. Note that the evaporation portion 4 may receive heat not only from a region same as an outer shape (installation area) of the heat source 100 but also from a region slightly larger than the outer shape thereof. On the other hand, the condensation portion 5 is a region formed in a periphery of the evaporation portion 4 and is a region other than the evaporation portion 4. Note that an electronic component of an electronic apparatus, for example, a CPU or the like can be exemplified as the heat source 100.

As illustrated in FIG. 2, the container 2 includes a container body 10, a top plate 11, and a bottom plate 12. The container body 10 can include, for example, copper, a copper alloy, aluminum, an aluminum alloy, and the like. Additionally, the top plate 11 and the bottom plate 12 can include, for example, copper, a copper alloy, aluminum, an aluminum alloy, iron, stainless steel, a composite material (Cu-SUS) of copper and stainless steel, a composite material (Cu-SUS-Cu) in which stainless steel is sandwiched with copper, a composite material (Ni-SUS) of nickel and stainless steel, a composite material (Ni-SUS-Ni) in which stainless steel is sandwiched with nickel, and the like.

In a case where the container body 10 includes a material having thermal conductivity higher than thermal conductivity of materials of the top plate 11 and the bottom plate 12, the top plate 11 and the bottom plate 12 may be formed from a material having high hardness in order to prevent deformation of the container 2. For example, in a case where the container body 10 includes copper having the high thermal conductivity, the top plate 11 and the bottom plate 12 may include a composite material of copper and stainless steel (Cu-SUS), a composite material (Cu-SUS-Cu) in which stainless steel is sandwiched with copper, a composite material (Ni-SUS) of nickel and stainless steel, a composite material (Ni-SUS-Ni) in which stainless steel is sandwiched with nickel, and the like.

Note that the top plate 11 and the bottom plate 12 may include the same material or different materials. Additionally, the top plate 11 and the bottom plate 12 may have the same thickness or different thicknesses. Furthermore, any one of the top plate 11 and the bottom plate 12 may be integrally formed with the container body 10. For example, a member functioning as both of a frame portion 10a and a column portion 10b of the container body 10 described later may be formed by molding, by press molding or the like, one of the top plate 11 and the bottom plate 12 to provide a groove, and the other one thereof may be joined to the molded member to form the container 2.

As illustrated in FIG. 1, the container body 10 includes: the frame portion 10a forming an outer shape of the container 2; and a plurality of column portions 10b arranged in a region surrounded by the frame portion 10a. The plurality of column portions 10b is arranged at certain intervals in a short direction of the container 2 and extends in parallel to a longitudinal direction of the container 2. The plurality of column portions 10b is provided in order to prevent expansion and dent in the thickness direction of the container 2. The plurality of column portions 10b functions as columns (reinforcing members) supporting the container 2, and secures mechanical strength of the thin vapor chamber 1. A gap is formed in each of between the frame portion 10a and the column portions 10b and between the adjacent column portions 10b, and a working fluid flow path 13 is formed in the gap. The working fluid flow path 13 of one or more embodiments includes a plurality of channels 13a (e.g., four). The longitudinal direction is the vertical direction in FIG. 1.

As illustrated in FIG. 2, the working fluid flow path 13 is hermetically sealed by joining the top plate 11 and the bottom plate 12 to the container body 10. The working fluid flow path 13 is surrounded by: a first surface 14 that receives heat from the heat source 100; a second surface 15 located on an opposite side of the first surface 14; and a connection surface 16 connecting the first surface 14 and the second surface 15. For example, the container 2 of one or more embodiments has a constitution in which the heat of the heat source 100 is received from the bottom plate 12 side, an upper surface of the bottom plate 12 is the first surface 14, a lower surface of the top plate 11 is the second surface 15, and a side surface of each column portion 10b (or an inner surface 10a1 of the frame portion 10a illustrated in FIG. 1) is the connection surface 16. The side surface of each column portion 10b faces a vapor flow path 17. The connection surface 16 of each column portion 10b is flat (in other words, not provided with a protruding and recessed portion), and capillary force is not generated only by the column portion 10b.

As illustrated in FIG. 1, the wick 3 is arranged in the working fluid flow path 13. In the wick 3, the working liquid is evaporated and becomes vapor inside the evaporation portion 4, the vapor is condensed in the condensation portion 5 and becomes the working liquid, and the working liquid is moved (returned) from the condensation portion 5 to the evaporation portion 4 by the capillary force. The wick 3 of one or more embodiments includes: a plurality of wick branch portions 20 (wick portions) arranged in the respective channels 13a of the working fluid flow path 13; a wick trunk portion 21 connecting root portions of the plurality of wick branch portions 20. Note that a width of each wick branch portion 20 and a width of the wick trunk portion 21 are formed same.

The wick 3 includes a mesh obtained by knitting a plurality of thin lines in a lattice pattern. As the thin lines forming the wick 3, a copper material having high thermal conductivity can be suitably used, for example. Each of the fine wires is formed with a diameter of several tens μm to several hundred μm, for example. As illustrated in FIG. 2, the wick 3 contacts the first surface 14 and the second surface 15 in the working fluid flow path 13. Note that each vapor flow path 17 of the working fluid is formed in a space between each side surface 3a of the wick 3 and each connection surface 16 arranged spaced apart from the side surface 3a.

A gap 18a formed at an interface between the wick 3, the first surface 14, and the second surface 15 functions as a liquid flow path 18 that makes the working liquid flow, and returns the working liquid from condensation portion 5 to the evaporation portion 4. Additionally, each gap 18b between the thin lines inside the wick 3 also functions as a liquid flow path 18 that makes the working liquid flow, and returns the working liquid from the condensation portion 5 to the evaporation portion 4. Note that carrying capacity of the working liquid is larger in the liquid flow path 18 of each gap 18a than in the liquid flow path 18 of each gap 18b because the gap 18b between the thin lines has a space smaller than the gap 18a formed at the interface between the wick 3, the first surface 14, and the second surface 15.

Returning to FIG. 1, the plurality of wick branch portions 20 forms a plurality of the liquid flow paths 18 described above. The plurality of wick branch portions 20 is inserted into the respective channels 13a from the wick trunk portion 21 and extends from the respective channels 13a to an installation region of the heat source 100, and respective tip portions of the wick branch portions are independently inserted into the evaporation portion 4. A first wick branch portion 20a and a fourth wick branch portion 20dextend from the condensation portion 5 along the inner surface 10a1 of the frame portion 10a and are inserted into the evaporation portion 4. Additionally, a second wick branch portion 20b and a third wick branch portion 20c extend from the condensation portion 5 between the adjacent column portions 10b and are inserted into the evaporation portion 4. The respective column portions 20 are formed between the first wick branch portion 20a and the second wick branch portion 20b, between the second wick branch portion 20b and the third wick branch portion 20c, and between the third wick branch portion 20c and the fourth wick branch portion 20d.

The tip portions of the plurality of wick branch portions 20 densely exist in the evaporation portion 4. Therefore, all of the vapor flow paths 17 are connected in the evaporation portion 4.

The plurality of wick branch portions 20 includes facing portions 23 facing each other interposing each vapor flow path 17 (space) in the evaporation portion 4. Specifically, the evaporation portion 4 is provided with: facing portions 23ab where the first wick branch portion 20a and the second wick branch portion 20b face each other; facing portions 23bc where the second wick branch portion 20b and the third wick branch portion 20c face each other; facing portions 23cd where the third wick branch portion 20c and the fourth wick branch portion 20d face each other; and facing portions 23 da where the fourth wick branch portion 20d and the first wick branch portion 20a face each other. Protruding and recessed portions 30 are formed at these facing portions 23.

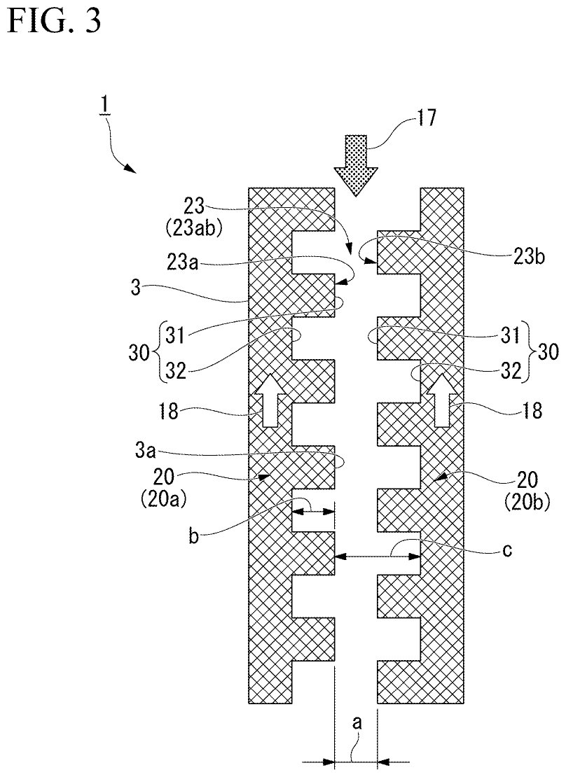

FIG. 3 is an enlarged view of facing portions 23 according to one or more embodiments. Note that FIG. 3 is a schematic view of the facing portions 23ab between the first wick branch portion 20a and the second wick branch portion 20b, but other facing portions 23 have similar constitutions.

As illustrated in FIG. 3, the protruding and recessed portions 30 are formed at the facing portions 23ab. The protruding and recessed portions 30 of one or more embodiments are formed respectively in both of: the facing portion 23a of the first wick branch portion 20a facing the second wick branch portion 20b; and the facing portion 23b of the second wick branch portion 20b facing the first wick branch portion 20a.

Each protruding and recessed portion 30 includes a plurality of protrusions 31 and a plurality of recesses 32, and the protrusions 31 and the recesses 32 are alternately arranged one by one along the vapor flow path 17. Each of the protrusions 31 and each of the recesses 32 in the protruding and recessed portion 30 are formed respectively in rectangular shapes in the plan view as illustrated in FIG. 3. In other words, a corner portion of each protrusion 31 and a corner portion of each recess 32 are formed respectively in a right angle. Such a protruding and recessed portion 30 can be formed by die cutting processing with a press machine. A length of each protrusion 31 and a length of each recess 32 have the same length in a direction along the vapor flow path 17. Note that the lengths of the protrusion 31 and the recess 32 in the direction along the vapor flow path 17 may be different from each other.

Additionally, each of the protrusions 31 of the protruding and recessed portion 30 formed at one of the facing portions 23ab (e.g., facing portion 23a) is formed in a manner facing each of the recesses 32 of the protruding and recessed portion 30 formed at the other one of the facing portions 23ab (e.g., facing portion 23b). In other words, the protrusions 31 (or the recesses 32) of the protruding and recessed portion 30 formed at the facing portion 23a and the protrusions 31 (or the recesses 32) of the protruding and recessed portion 30 formed at the facing portion 23b are arranged so as to be alternate.

A reference symbol “a” indicated in FIG. 3 represents a main flow path width of the vapor flow path 17. The main flow path width of the vapor flow path 17 represents a space width between side surfaces 3a of the wick 3 facing each other in a case of having no protruding and recessed portion 30. Additionally, a reference symbol “b” indicated in FIG. 3 represents a length (depth) from a tip of each protrusion 31 to a bottom of each recess 32 in each protruding and recessed portion 30. The tip of each protrusion 31 is the side surface 3a of the wick 3, and each recess 32 is a groove with the depth b formed on the side surface 3a. The depth b is formed to have a size of, for example, about 2 mm when each wick branch portion 20 illustrated in FIG. 1 is formed to have a width of 5 mm.

A reference symbol “c” indicated in FIG. 3 represents a maximum width of the vapor flow path 17 from a tip of each protrusion 31 formed in the facing portion 23a to a bottom of each recess 32 of the facing portion 23b facing the protrusion 31. The maximum width c of the vapor flow path 17 is formed larger than the main width a, and for example, when the main width a is formed to have a size of 2 mm, the maximum width c is formed to have a size of about 4 mm that is twice the size of the main width. In one or more embodiments, since the protrusions 31 (or the recesses 32) of the protruding and recessed portion 30 formed at the facing portion 23a and the protrusions 31 (or the recesses 32) of the protruding and recessed portion 30 formed at the facing portion 23b are arranged so as to be alternate, the maximum width c of the vapor flow path 17 is constant.

Subsequently, a heat transport cycle by the vapor chamber 1 having the above-described constitution will be described.

In the vapor chamber 1, the working liquid inside the evaporation portion 4 is evaporated by receiving the heat generated at the heat source 100. In the evaporation portion 4, the working liquid having permeated the wick 3 is evaporated. The vapor generated in the evaporation portion 4 flows through the inside of each vapor flow path 17 to the condensation portion 5 having a pressure and a temperature lower than those of the evaporation portion 4. As illustrated in FIG. 2, since the wick 3 is arranged spaced apart from each connection surface 16, the vapor can flow along the side surface 3a of the wick 3.

In the condensation portion 5, the vapor having reached the condensation portion 5 is cooled and condensed. The working liquid generated in the condensation portion 5 permeates the wick 3 and is returned from the condensation portion 5 to the evaporation portion 4. The wick 3 has the plurality of wick branch portions 20 extending from the condensation portion 5 to the evaporation portion 4, and returns the working liquid from the condensation portion 5 to the evaporation portion 4 via the liquid flow paths 18 formed by the respective wick branch portions 20. Since the wick branch portions 20 each contact the first surface 14 and the second surface 15 of the working fluid flow path 13 from the condensation portion 5 to the evaporation portion 4 as illustrated in FIG. 2, the wick branch portions function as the columns (reinforcing members) supporting the container 2 and secure the mechanical strength of the thin vapor chamber 1.

By the way, since the tip portions of the respective wick branch portions 20 densely exist in the evaporation portion 4, a pressure loss of the vapor tends to be large in the vapor flow path 17 formed between the facing portions 23 of these wick branch portions 20. Therefore, in one or more embodiments, the protruding and recessed portions 30 are formed at these facing portions 23. The pressure loss is an energy loss in a flow direction, which is caused by a state in which shear stress acting on a pipe acts on fluids as friction in a case of having a laminar flow in a flow inside a pipe. Such shear stress becomes maximum on a wall surface forming a flow path. In a conventional wick structure without having any protruding and recessed portion 30, each side surface 3a of a wick 3 is uniformly arranged relative to each vapor flow path 17, whereas in the wick structure of one or more embodiments, the wall surface can be set away from each vapor flow path 17 by providing the recesses 32 despite a fact that the main width a of the vapor flow path 17 is similar to that in the conventional structure as illustrated in FIG. 3. Therefore, compared to the conventional structure, the pressure loss can be reduced. Therefore, in one or more embodiments, even though all of the vapor flow paths 17 are connected via the evaporation portion 4, vapor pressures in all of the vapor flow paths 17 can be made uniform while reducing the pressure loss.

Note that in one or more embodiments, the facing portions 23 are provided only in the evaporation portion 4. Note that positions of facing portions 23 are not limited to only the evaporation portion 4.

Furthermore, in the thin vapor chamber 1, a thin material is used as the material of the container 2 in order to secure an internal space as large as possible. Therefore, in the vapor chamber 1 having a negative pressure inside thereof, in a case where the width of each vapor flow path 17 is simply increased in order to reduce the pressure loss of the vapor, the vapor chamber may be easily deformed. Therefore, in the wick structure of one or more embodiments, the columns supporting the container 2 are made to partly remain to reinforce the container 2 by forming not only the recesses 32 but also the protrusions 31. In other words, according to the wick structure of one or more embodiments, since the protruding and recessed portions 30 are formed in the facing portions 23, it is possible to reinforce the container 2 while widening the flow path width of the vapor flow path 17. Therefore, according to the wick structure of one or more embodiments, the pressure loss of the vapor can be reduced and also the mechanical strength of the container 2 can be secured.

Additionally, in one or more embodiments, as illustrated in FIG. 2, the protrusions 31 formed at one of the facing portions 23 are provided in a manner facing the recesses 32 of the other one of the facing portions 23. According to this constitution, even when the recesses 32 are formed at the wick branch portions 20, the protrusions 31 protrude to the recesses 32 from the wick branch portion 20 facing the wick branch portion 20, and therefore, the width of each vapor flow path 17 does not becomes larger than the width c. Additionally, since the width of the vapor flow path 17 between the facing portions 23 is kept constant at the width c, the width of the vapor flow path 17 does not become locally narrow, and the pressure loss of the vapor can be suitably reduced.

Furthermore, in one or more embodiments, as illustrated in FIG. 1, the facing portions 23 of the plurality of wick branch portions 20 are provided in the evaporation portion 4. Since the protruding and recessed portions 30 are formed at these facing portions 23, thermal resistance in the evaporation portion 4 can be reduced. In other words, in the case where each wick branch portion 20contacts the first surface 14 and the second surface 15 of the working fluid flow path 13 as illustrated in FIG. 2, evaporation occurs at the side surface 3a (portion contacting each vapor flow path 17). Therefore, since the protruding and recessed portion 30 is formed at the portion of each wick branch portion 20 contacting the vapor flow path 17, it is possible to secure the evaporation area of the working fluid larger than the evaporation area in the conventional wick structure not having any protruding and recessed portion 30, and the thermal resistance in the evaporation portion 4 can be reduced. Furthermore, in one or more embodiments, all of the vapor flow paths 17 are connected via the evaporation portion 4. Therefore, the vapor pressures in all of the vapor flow paths 17 can be made uniform.

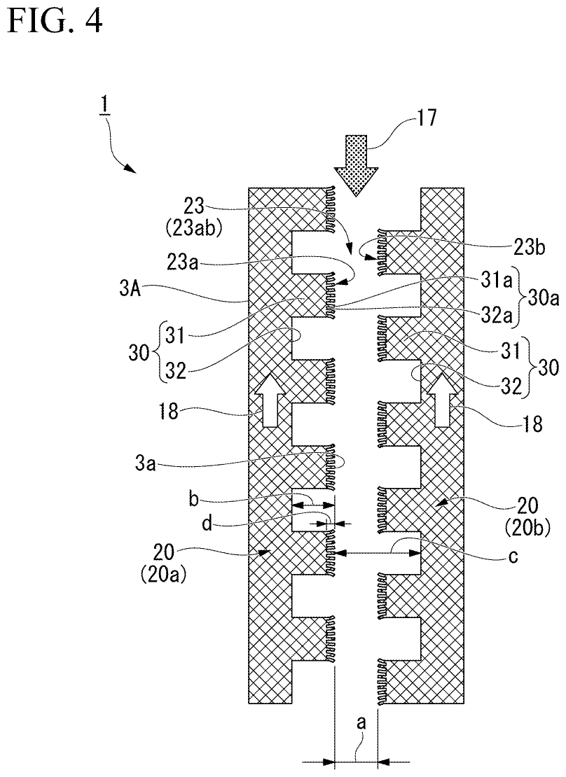

Furthermore, the thermal resistance in the evaporation portion 4 can be more reduced by adopting the constitution as illustrated in FIG. 4.

FIG. 4 is an enlarged view of a modified example of the facing portions 23 according to one or more embodiments.

In a wick 3A illustrated in FIG. 4, a second protruding and recessed portion 30a is formed in a tip of a protrusion 31 of each protruding and recessed portion 30. The second protruding and recessed portion 30a is formed by making a plurality of cuts at the tip of the protrusion 31 of the protruding and recessed portion 30 with a cutter or the like. The second protruding and recessed portion 30a includes protrusions 31a and recesses 32a, and the protrusions 31a extend outward to the vapor flow path 17 like brush bristles.

A reference symbol “d” in FIG. 4 represents a length (depth) from the tip of each protrusion 31a to a bottom of each recess 32a of the second protruding and recessed portion 30a. The tip of the protrusion 31a is each side surface 3a of the wick 3, and the recess 32a is a groove with the depth d formed on the side surface 3a. When the depth b is formed to have a size of 2 mm, the depth d is formed to have a size of, for example, about ¼ of the depth b, namely, about 0.5 mm. According to this constitution, the larger evaporation area can be secured than in the wick construction illustrated in FIG. 3 because of the second protruding and recessed portions 30a, and the thermal resistance in the evaporation portion 4 can be further reduced.

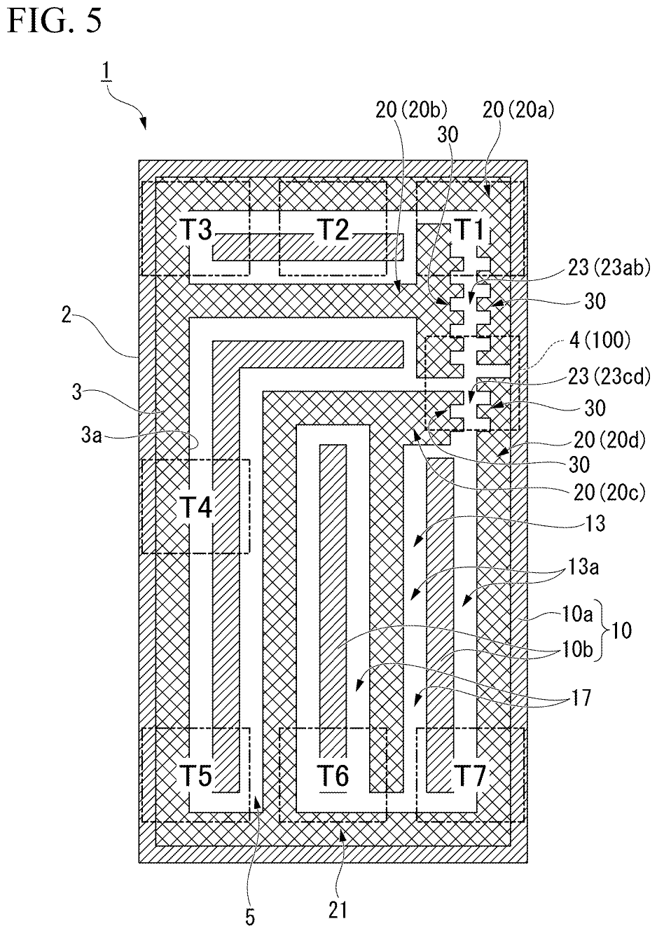

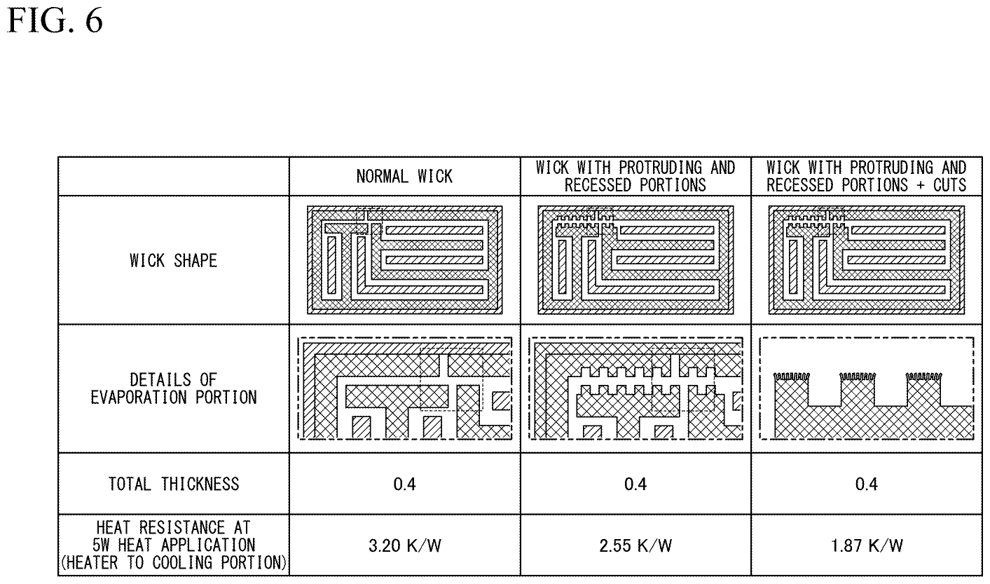

FIG. 5 is a planar cross-sectional view of a test device that evaluates performance of the vapor chamber 1 according to one or more embodiments. FIG. 6 is a table illustrating test results by the test device illustrated in FIG. 5.

The test device as illustrated in FIG. 5 is prepared in order to evaluate the performance of the vapor chamber 1.

This test device has a constitution in which the heat source 100 (heater sensor) is attached to one plate surface (e.g., back surface) of the vapor chamber 1 and a plurality of temperature sensors T1 to T7 is attached to the other plate surface (e.g., front surface) of the vapor chamber 1. A temperature of the evaporation portion 4 is measured by the heater sensor that is the heat source 100, and a temperature of the condensation portion 5 is measured by the plurality of temperature sensors T1 to T7, and the performance of the vapor chamber 1 is evaluated based on thermal resistance.

The thermal resistance is obtained by Equation (1) below. Q [W] is a heat quantity (so-called heat application quantity) applied by the heat source 100 per unit time. Th [° C.] is a temperature of the heat source 100 (evaporation portion 4). T1 to T7 [° C.]are temperatures of the condensation portion 5 detected by the temperature sensors T1 to T7.

The heat application quantity is an electric power quantity in a case where the heat source 100 is an electric heater. The temperature Th is measured in a state where the heat application quantity from the heat source 100 and a heat dissipation quantity through the vapor chamber 1 are balanced, and equilibrium is achieved. Note that the higher heat transport capacity of the vapor chamber 1 is, the smaller the thermal resistance is.

$$\begin{matrix}( Equation 1 ) & \\ Rsp = \frac{Th - Ave ( T 1 \sim 7 )}{Q} & ( 1 )\end{matrix}$$

FIG. 6 illustrates, as comparative examples, test results between a normal wick structure having no protruding and recessed portion 30 in a facing portion 23, the wick structure of one or more embodiments having the protruding and recessed portions 30 formed in each facing portion 23, and the wick structure of the modified example having the second protruding and recessed portion 30a (cuts) formed at a tip of each protrusion 31. Note that total thicknesses of the test devices of the vapor chambers 1 having the respective wick structures are the same. Comparing the test results illustrated in FIG. 6, the thermal resistance in the wick structure of one or more embodiments having the protruding and recessed portions 30 formed is reduced by about 20% (the heat transport capacity is increased by about 20%) more than in the normal wick structure. Additionally, the thermal resistance in the wick structure of the modified example having the second protruding and recessed portions 30a formed is further reduced by about 40% (the heat transport capacity is increased by about 40%) than in the normal wick structure. Thus, according to the wick structure illustrated in FIGS. 3 and 4, it is found that the evaporation area can be expanded in the evaporation portion 4 and the thermal resistance can be reduced.

As described above, according to one or more embodiments, adopted is the constitution including: the container 2 enclosing the working fluid therein and including the evaporation portion 4 that evaporates the enclosed working fluid and the condensation portion 5 that condenses the evaporated working fluid; and the wick 3 arranged inside the container 2 and adapted to move the condensed working fluid from the condensation portion 5 to the evaporation portion 4 by the capillary force, in which the wick 3 includes the plurality of wick branch portions 20 forming the plurality of liquid flow paths 18 from the condensation portion 5 to the evaporation portion 4, the plurality of wick branch portions 20 includes facing portions 23 facing each other interposing each vapor flow path 17 of the working fluid, and the protruding and recessed portions 30 are formed at the facing portions 23. Therefore, it is possible to achieve the vapor chamber 1 in which the pressure loss of the vapor of the working fluid is reduced and also the mechanical strength of the container 2 can be secured. Additionally, according to this constitution, the evaporation area of the working fluid can be expanded, the thermal resistance can be reduced, and the heat transport capacity can be increased in the evaporation portion 4.

While embodiments of the present invention have been described and illustrated, it should be understood that the embodiments are examples and not intended to limit the present invention. Additions, omissions, substitutions, and other changes can be made without departing from the scope of the present invention. Therefore, the present invention should not be deemed as limited by the above description but is limited by the scope of the claims.

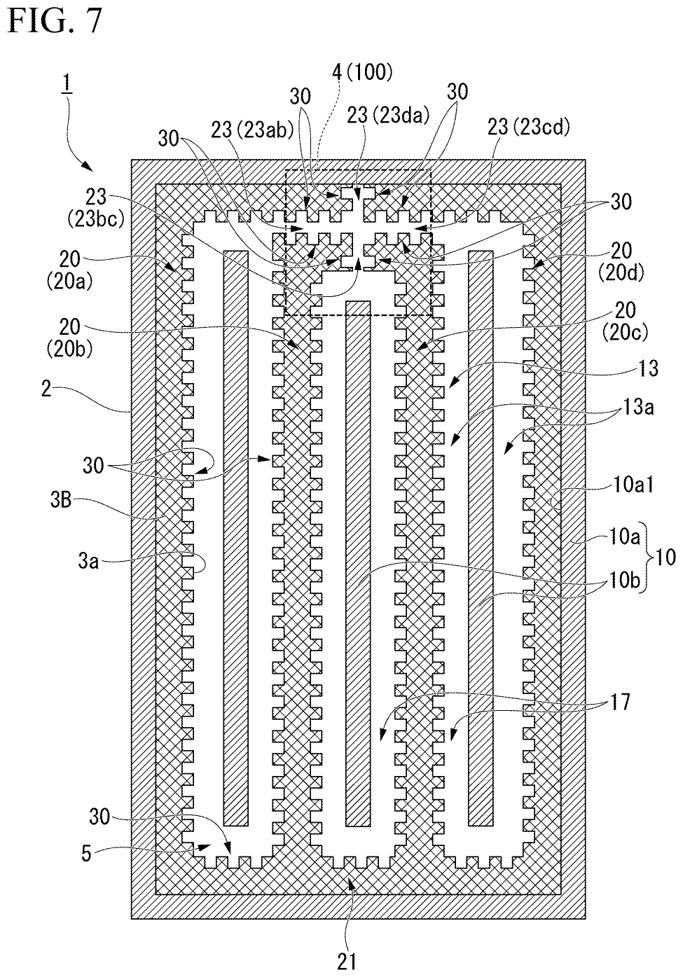

For example, modified examples illustrated in FIGS. 7 to 9C can be adopted. In the following description, components identical or equivalent to components of the above-described embodiments will be denoted by the same reference symbols, and the description thereof will be simplified or omitted.

In a wick 3B according to the modified example illustrated in FIG. 7, the protruding and recessed portions 30 are formed at not only the facing portions 23 but also the entire side surface 3a contacting the vapor flow paths 17 other than the facing portions 23. According to this constitution, a pressure loss in all of the vapor flow paths 17 is reduced, and the mechanical strength of the container 2 can be secured. In other words, the side surfaces (connection surfaces) of the column portions 10b are flat whereas the protruding and recessed portions 30 are formed on the surfaces of the plurality of wick branch portions 20 facing the side surfaces of the column portions 10b.

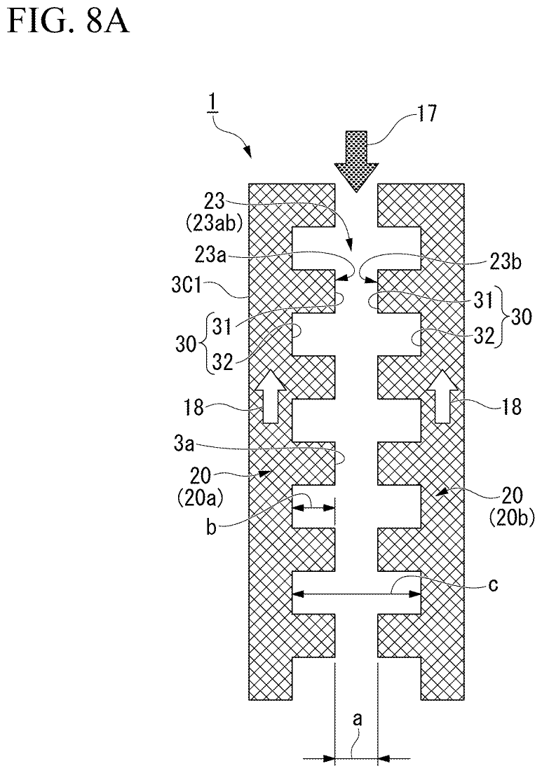

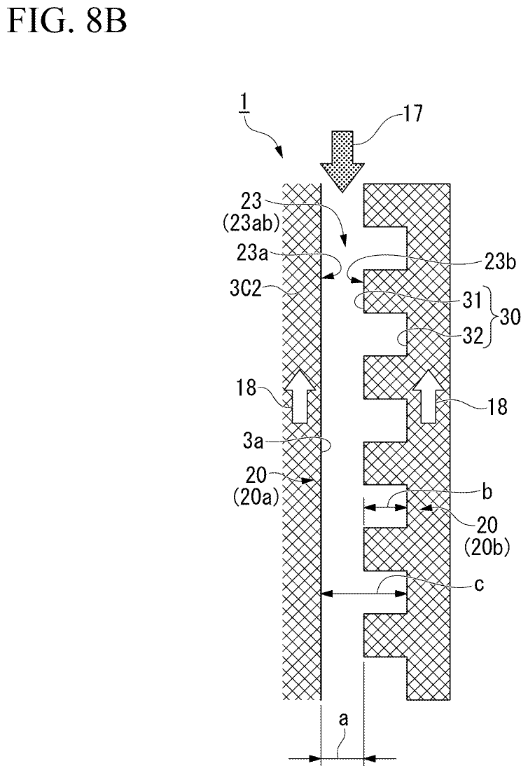

In a wick 3C1 according to the modified example illustrated in FIG. 8A, the protrusions 31 of the protruding and recessed portion 30 formed at one of the facing portions 23ab (e.g., facing portion 23a) face the protrusions 31 of the protruding and recessed portion 30 formed at the other one of the facing portions 23ab (e.g., facing portion 23b).

Furthermore, in the wick 3C1 according to the modified example illustrated in FIG. 8B, no protruding and recessed portion 30 is formed at one of the facing portions 23ab (e.g., facing portion 23a), and the protruding and recessed portion 30 is formed at the other one of the facing portions 23ab (e.g., facing portion 23b).

Even in the constitutions illustrated in FIGS. 8A and 8B, the wall surface can be set away from each vapor flow path 17 in a manner similar to the above-described embodiments, the pressure loss is reduced more than in the conventional structure, and also the mechanical strength of the container 2 can be secured. Note that, from the viewpoint of reducing the pressure loss, the wick structure having many recesses 32 illustrated in FIG. 8B may be used instead of the wick structure illustrated in FIG. 8A, and additionally, the wick structure having the constant maximum width c illustrated in FIGS. 3 and 4 may be used instead of the wick structure illustrated in FIG. 8A.

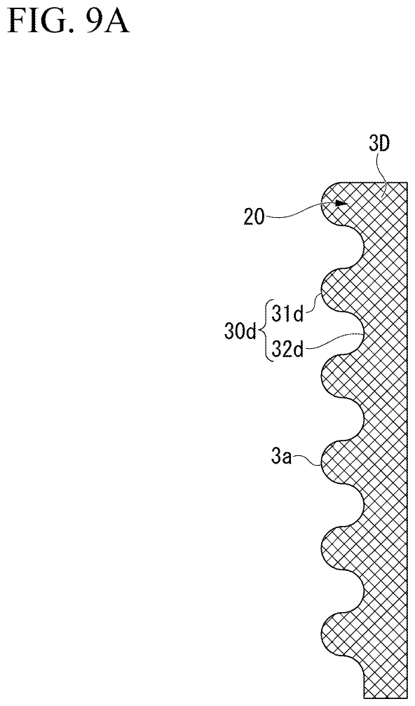

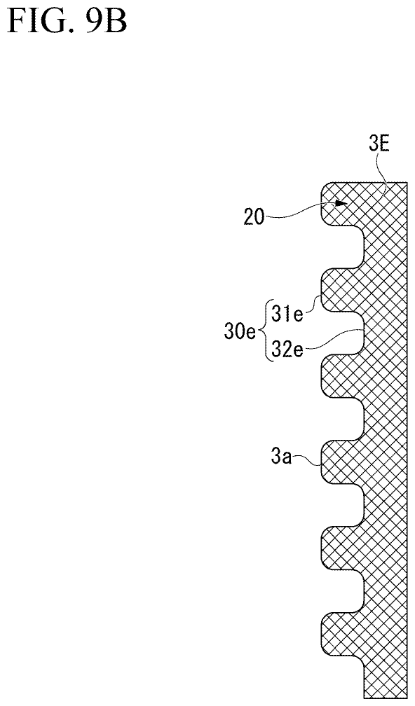

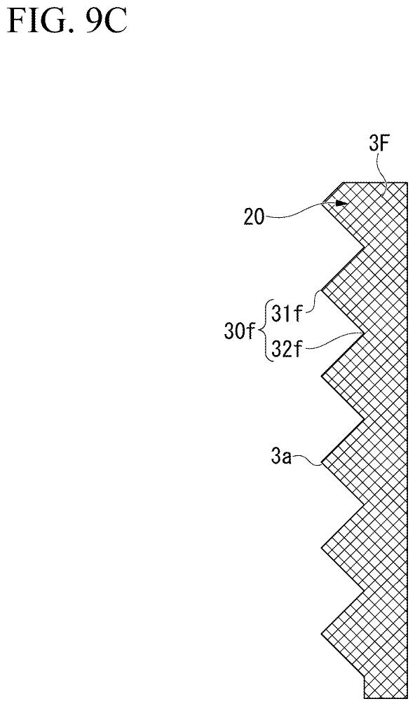

A wick 3D according to the modified example illustrated in FIG. 9A includes a protruding and recessed portion 30d formed in a waveform, and protrusions 31d and recesses 32d are formed respectively in curved shapes in the plan view.

A wick 3E according to the modified example illustrated in FIG. 9B includes a protruding and recessed portion 30e in which corners are rounded, and protrusions 31e and recesses 32e are formed respectively in substantially rectangular shapes in the plan view.

A wick 3F according to the modified example illustrated in FIG. 9C includes a protruding and recessed portion 30f having triangular shapes, and protrusions 31f and recesses 32f are formed respectively in substantially triangular shapes in the plan view.

Even in the constitutions illustrated in FIGS. 9A to 9C, the wall surface can be set away from each vapor flow path 17 in a manner similar to the above-described embodiments, and therefore, the pressure loss is reduced more than in the conventional structure, and also the mechanical strength of the container 2 can be secured. According to the constitutions illustrated in FIGS. 9A to 9C, when the protruding and recessed portions 30d to 30f are formed by pressing work, die cutting can be more easily performed than in the constitution illustrated in FIG. 3 because there is no right-angle portion. Note that, from the viewpoint of increasing the evaporation area of the working fluid, the wick structure having the rectangular shapes illustrated in FIGS. 3 and 4 in which a long contour of an edge of the side surface 3a can be secured may be used.

Furthermore, in the above-described embodiments, the constitution in which the wick 3 is divided into the plurality of branch portions to form the plurality of liquid flow paths 18 has been described, for example, however; it may be also possible to have a constitution in which a plurality of wicks 3 is arranged inside the container 2 to form the plurality of liquid flow paths 18. In other words, the plurality of wick portions may include the plurality of wicks 3.

Additionally, facing portions of the wick portions may be provided in a place other than the evaporation portion 4.

Furthermore, in the above embodiments, the constitution in which the wick 3 includes the mesh has been described, for example, however; the wick 3 may include fibers, metal powder, felt, grooves (channels) formed in the container 2, or a combination thereof.

Additionally, in the above embodiments, the vapor chamber 1 is exemplified as the heat dissipation module, for example, however; the above constitution may also be applied to a heat pipe that is a different form of the heat dissipation module.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF REFERENCE NUMERALS

1: Vapor chamber

2: Container

3: Wick

3a: Side surface

4: Evaporation portion

5: Condensation portion

16: Connection surface

17: Vapor flow path

18: Liquid flow path

20: Wick branch portion (wick portion)

23: Facing portion

30: Protruding and recessed portion

31: Protrusion

32: Recess

1. A heat dissipation module comprising:
a container that encloses a working fluid and that comprises:
an evaporation portion that evaporates the enclosed working fluid; and
a condensation portion that condenses the evaporated working fluid; and
a wick disposed inside the container and that moves the condensed working fluid from the condensation portion to the evaporation portion using capillary force, wherein:
the wick comprises a plurality of wick portions that form a plurality of liquid flow paths that extend from the condensation portion to the evaporation portion,
a vapor flow path of the working fluid is disposed between each of the plurality of wick portions, and all of the vapor flow paths are connected in the evaporation portion,
the plurality of wick portions comprises facing portions that face each other and interpose the vapor flow path at least in the evaporation portion, and
a first protruding and recessed portion is disposed on at least one of the facing portions.

2. The heat dissipation module according to claim 1, wherein the facing portions are disposed only in the evaporation portion.

3. The heat dissipation module according to claim 1, wherein
the first protruding and recessed portion is disposed on both of the facing portions of each of the plurality of wick portions, and
a protrusion that is disposed at one of the facing portions faces a recess on the other of the facing portions.

4. (canceled)

5. The heat dissipation module according to claim 1, wherein a second protruding and recessed portion is disposed on a tip of a protrusion of the first protruding and recessed portion.

6. The heat dissipation module according to claim 1, further comprising:
a column portion between the plurality of wick portions.

7. The heat dissipation module according to claim 6, wherein
a side surface of the column portion is flat, and
the first protruding and recessed portion is disposed on a surface of the wick that faces a side surface of the column portion.

8. The heat dissipation module according to claim 1, wherein the first protruding and recessed portion is disposed on the entire side surface of the wick that faces the vapor flow path.

9. The heat dissipation module according to claim 1, wherein the facing portions are not disposed in the condensation portion.

10. The heat dissipation module according to claim 1, wherein a protrusion and a recess of the first protruding and recessed portion have triangular shapes in a plan view of the container.
